(19) United States
(12) Patent Application Publication
(10) Pub. No.: US 2008/0001103 A1
(43) Pub. Date: Jan. 3, 2008

(54) Electron-beam lithography method and apparatus, and program thereof

(75) Inventor: Takashi Sugimura, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 11/812,125

(22) Filed: Jun. 15, 2007

(30) Foreign Application Priority Data
Jun. 28, 2006 (JP) 2006-177935

(51) Int. Cl. G03F 7/20

(52) U.S. Cl. 250/492.22; 250/492.2

(57) ABSTRACT

An electron-beam lithography apparatus, an electron-beam lithography method, and an electron-beam lithography program are provided that prevent any deformation in pattern dimension at a connection from being recognized as a false defect even with higher-sensitivity optical defect inspection. A circuit pattern containing a plurality of areas with high repetition rates, each of which having more repetitive patterns than surrounding areas of each of the areas with high repetition rates, is split into a plurality of drawing areas so that a boundary between adjacent drawing areas is laid between adjacent areas with high repetition rates. The circuit pattern is drawn on a drawing target for each of the drawing areas.

### BACKGROUND OF THE INVENTION

1. Field of the Invention

The present invention relates to an electron-beam lithography method, an electron-beam lithography apparatus, and an electron-beam lithography program which draws a pattern on a drawing target by means of an electron beam.

Priority is claimed on Japanese Patent Application No. 2006-177935, filed Jun. 28, 2006, the content of which is incorporated herein by reference.

2. Description of Related Art

A semiconductor-device manufacturing process involves a step of forming a circuit pattern on a semiconductor wafer as a part thereof. In the step of forming the circuit pattern, a resist material is covered on the semiconductor wafer and the electron beam is irradiated focusing at a given position thereon to make a drawing.

As one method for drawing a pattern on a semiconductor wafer, a method using direct drawing without any intermediates such as a photomask is known. According to this method, the electron beam moves through irradiated positions while repeating an on-off cycle of electron-beam irradiation so as to irradiate only against desired positions. Similarly, in the manufacturing process of photomasks used with a projection exposure apparatus, patterns are drawn by the direct drawing technique.

Now, referring to FIG. 1, the method for drawing a pattern on the drawing target using the direct drawing technique is described below. An electron-beam lithography apparatus, which makes drawings by means of an electron beam 103, splits the whole pattern to be drawn into a plurality of areas. Drawing is sequentially made in each of the split areas. In this case, as soon as drawing is finished in one area, a stage mounting the drawing target moves to a next adjacent area to make a drawing there. It should be noted that the space of each of the areas is referred to as a deflection area (in FIG. 1, deflection areas 101, 102) because it is limited by the allowable deflection width of the electron beam 103. The boundary between the adjacent deflection areas is referred to as a connection (in FIG. 1, a connection 107). Herein, the space of the deflection area, which falls within a rectangle defined by the maximum deflection width in the X-direction and the maximum deflection width in the Y-direction of the electron-beam lithography apparatus, has been determined depending on such factors as throughput, precision of the deflection position, and precision of the deflected output.

Among the beam outputs from the electron beam 103 during drawing, a variation occurs depending on positions (deflection positions) in the deflection area. FIG. 2 is a graph showing the correlation between the deflection positions and the beam outputs. As shown in FIG. 2, a variation has occurred among the beam outputs depending on the deflection positions within the deflection width. FIG. 3 is a chart showing a distribution of the beam outputs within areas across the connections 107. As shown in FIG. 3, since the deflection position of the electron beam 103 is reset to its initial state at the connection 107, the beam outputs do not exhibit continuous distribution, which may lead to a rapid change therein.

FIG. 5 is a view showing the arrangements of deflection areas 106 and patterns. In this figure, as an example, the circuit pattern of Dynamic Random Access Memory (DRAM) is shown. The circuit pattern has memory cell mat areas 105 (i.e., MC_11 to MC_67) arranged in a reticular pattern therein. As shown in the figure, the connection 107 may overlap the memory cell mat area 105 because the deflection area 106 is determined depending on such factors as throughput, precision of the deflection position, and precision of the deflected output as described before.

FIG. 6 is a view showing the pattern geometry in the vicinity of the connection 107 when the circuit pattern overlaps the connection 107. At the connection 107, a rapid change in beam output induces a sudden deformation in dimension of a drawn pattern.

In connection with the aforementioned problem, Japanese Unexamined Patent Application, First Publication No. 2004-144885 discloses a method for correcting the optical intensity of a laser beam, which is intended to avoid deterioration in dimension precision by correcting dimension deforming factors for each beam. The method for correcting the laser beam corrects the optical intensity of the laser beam based on the difference between the design width of a test pattern and the width of a drawn test pattern.

Moreover, Japanese Unexamined Patent Application, First Publication No. 2003-241390 discloses a technique for estimating the effects on the geometry after the resist has been developed to resolve the problem of limited drawing precision while any error at the boundary between the drawing fields and any error in drawing position are accurately determined.

Furthermore, Japanese Unexamined Patent Applications, First Publication Nos. 2004-61795 and 2004-333942 disclose a multi-pass drawing technique. In order to suppress any sudden change in dimension in the vicinity of the connection, this technique draws one pattern by making drawings more than once with portions of the drawing areas overlapping each other. FIGS. 4A to 4F are drawings illustrating the method for applying this multi-pass drawing technique. Specifically, FIGS. 4A, 4C, and 4E indicate the arrangement of the drawing areas, and FIGS. 4B, 4D, and 4F are graphs describing the position-dependence of the beam outputs. FIGS. 4A and 4B are the views illustrating single-pass drawing (i.e., not multi-pass drawing), FIGS. 4C and 4D are the views illustrating double-pass drawing, and FIGS. 4E and 4F are views illustrating quadruple-pass drawing. In the examples shown in FIGS. 4A and 4B, as soon as drawing is finished in one area (represented by a symbol a), drawing is made in its adjacent drawing area (represented by a symbol b) with no overlap on the area a. At that time, as aforementioned, a rapid change in beam output occurs at the connection. On the other hand, in the examples shown in FIGS. 4C and 4D, the second area b to be drawn partially overlaps the first area a already drawn. By moving the electron beam through the drawing areas with partial overlap between adjacent areas as described above, all the drawing areas are doubly drawn. In the examples shown in FIGS. 4E and 4F, quadruple-pass drawing (in FIG. 4E, drawing areas a to d) is applied on all the drawing areas. In the examples shown in FIGS. 4C to 4F, the overlap-drawing technique averages the beam outputs. The variation in beam output reduces as the number of overlaps increases. This is because the reduced variation in beam output suppresses any rapid change in beam output at the connection.

Recently, as the sizes of patterns of semiconductor devices have increasingly reduced, the need for a higher sensitive defect inspection technique has risen. The defect inspection techniques are largely divided into two types, i.e., an optical technique and a scanning electron microscope (SEM) technique. The optical defect inspection technique has an advantage of fast inspection over wider coverage. It is also capable of giving information on the size and color of a detected defect as well as of detecting defects occurring at a relatively lower layer. A major object of optical defect inspection technique is to detect defects. Accordingly, with regard to this type of technique, as the sizes of patterns have been reduced, the sensitivity has been made higher so as to detect even minute defects in reduced-size patterns. However, the higher-sensitivity optical defect inspection technique caused any aforementioned deformation in pattern dimension at the connection to be recognized as false defects in some cases. Frequent occurrence of false defects in the vicinity of the connection became a large barrier to successful higher-sensitivity optical defect inspection from the aspects of quality control and the improvement of yield.

In addition, even with the aforementioned multi-pass drawing technique, the higher-sensitive optical defect inspection technique causes the deformation in pattern dimension at the connection to be recognized as false defects.

### SUMMARY OF THE INVENTION

An object of the present invention is to provide an electron-beam lithography apparatus, an electron-beam lithography method, and an electron-beam lithography program that prevent any deformation in pattern dimension at the connection from being recognized as a false defect even with higher-sensitivity optical defect inspection.

An electron-beam lithography method according to an aspect of the present invention includes: a drawing area setting step of splitting a circuit pattern containing a plurality of areas with high repetition rates, each of which having more repetitive patterns than surrounding areas of each of the areas with high repetition rates, into a plurality of drawing areas so that a boundary between adjacent drawing areas is laid between adjacent areas with high repetition rates; and a drawing step of drawing the circuit pattern on a drawing target for each of the drawing areas.

In the electron-beam lithography method, the circuit pattern may be a DRAM circuit pattern, and each of the areas with high repetition rates may be a memory cell mat area containing an area where a plurality of memory cells are arranged into an array.

In the electron-beam lithography method, the drawing target may be a mask used in an electron-beam lithography apparatus.

In the electron-beam lithography method, the drawing target may be a semiconductor wafer.

In the electron-beam lithography method, a single-pass drawing may be made on the drawing target at the drawing step.

In the electron-beam lithography method, each of the drawing areas may be narrower than an area where an exposure device, which makes a drawing on the drawing target, can deflect an electron beam.

An electron-beam lithography apparatus according an aspect of the present invention includes: an exposure device which makes a drawing on a drawing target by means of an electron beam; and a control device which controls the operation of the exposure device, wherein the control device includes: a drawing area determination section which splits a circuit pattern containing a plurality of areas with high repetition rates, each of which having more repetitive patterns than surrounding areas of each of the areas with high repetition rates, into a plurality of drawing areas so that a boundary between adjacent drawing areas is laid between adjacent areas with high repetition rates; and a drawing section which allows the exposure device to draw the circuit pattern on the drawing target for each of the drawing areas.

In the electron-beam lithography apparatus, the circuit pattern may be a DRAM circuit pattern, and each of the areas with high repetition rates may be a memory cell mat area containing an area where a plurality of memory cells are arranged into an array.

In the electron-beam lithography apparatus, the drawing target may be a mask used in the electron-beam lithography apparatus.

In the electron-beam lithography apparatus, the drawing target may be a semiconductor wafer.

In the electron-beam lithography apparatus, the drawing section may allow the exposure device to make a single-pass drawing.

In the electron-beam lithography apparatus, each of the drawing areas may be narrower than an area where the exposure device can deflect the electron beam.

During the optical defect inspection process, a sudden deformation in pattern dimension in the drawing area with a high repetition rate is observed as color shading in a stripe-pattern or reticular pattern and may be recognized to be a defect. As described above, by matching the boundary between the drawing areas (i.e., the connection) to the boundary between the areas with high repetition rates, any rapid deformation in pattern dimension may be suppressed at least in the areas with high repetition rates. Accordingly, even with the higher-sensitive optical defect inspection technique, the probability of a deformation in pattern dimension at the connection being recognized as a false defect is reduced.

An electron-beam lithography program according to an aspect of the present invention is a computer program for allowing a computer to execute the aforementioned electron-beam lithography method.

According to an aspect of the present invention, an electron-beam lithography apparatus, an electron-beam lithography method, and an electron-beam lithography program are provided that can prevent any deformation in pattern dimension at the connection from being recognized as a false defect even with the high-sensitivity optical defect inspection technique.

### BRIEF DESCRIPTION OF THE DRAWINGS

FIG. 1 is a view illustrating the electron-beam lithography method employed in the electron-beam lithography apparatus.

FIG. 2 is a graph showing the correlation between the deflection positions and the beam outputs during drawing.

FIG. 3 is a chart showing the distribution of the beam outputs within the areas across the connections.

FIG. 4A is view showing the arrangement of the areas to be drawn without multi-pass drawing.

FIG. 4B is a graph describing the position-dependence of the beam outputs without multi-pass drawing.

FIG. 4C is a view showing the arrangement of the areas to be drawn with double-pass drawing.

FIG. 4D is a graph describing the position-dependence of the beam outputs with double-pass drawing.

FIG. 4E is a view showing the arrangement of the areas to be drawn with quadruple-pass drawing.

FIG. 4F is a graph showing the position-dependence of the beam outputs with quadruple-pass drawing.

FIG. 5 is a view showing the correlation between the circuit pattern and the drawing areas according to the related art.

FIG. 6 is a view showing the deformation in pattern dimension at the connection.

FIG. 7 is a block diagram showing the configuration of the electron-beam lithography apparatus according to an embodiment of the present invention.

FIG. 8 is a view showing the correlation between the drawing areas and the circuit pattern in the embodiment of the present invention.

FIG. 9 is a flowchart illustrating the electron-beam lithography method according to the embodiment of the present invention.

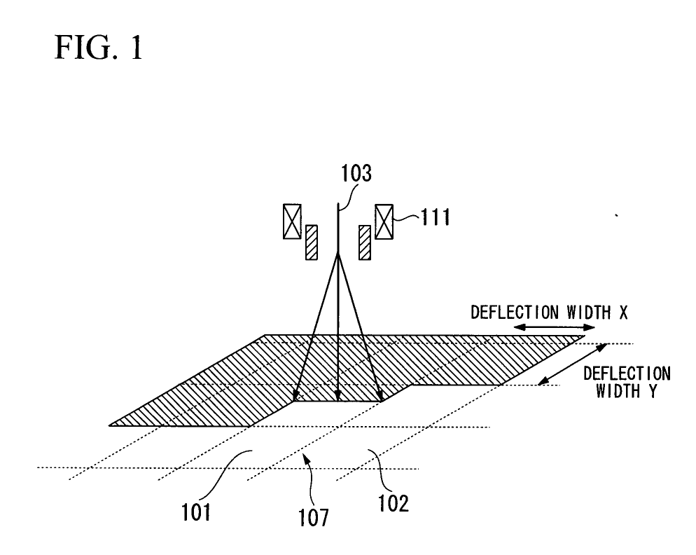

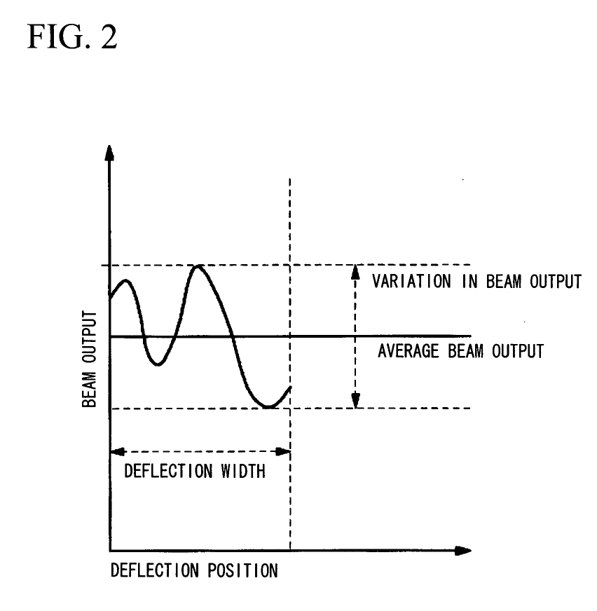

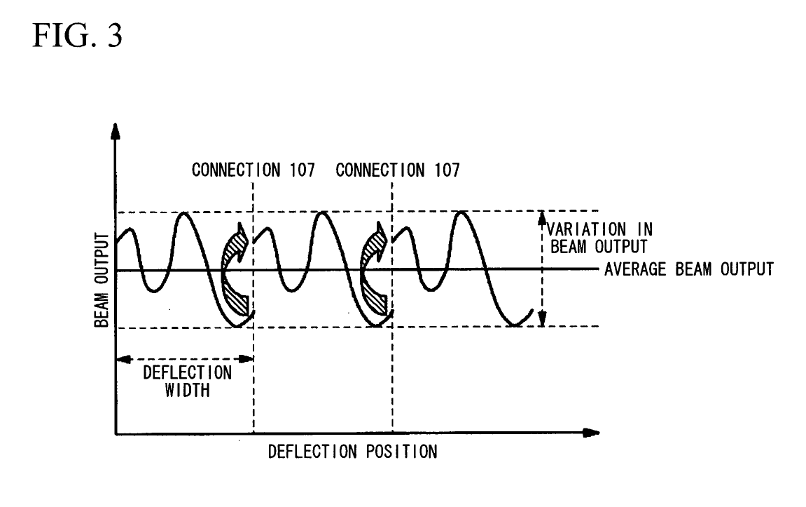

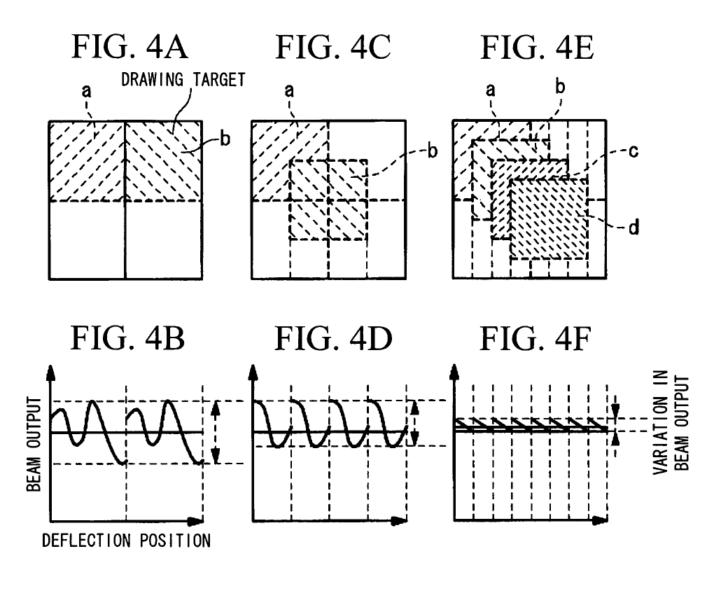

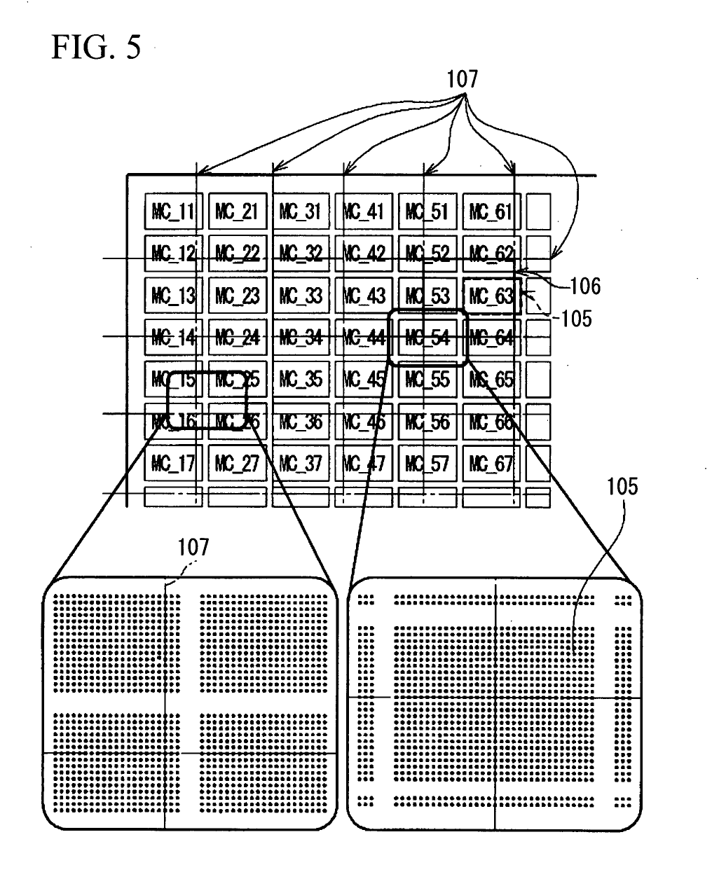

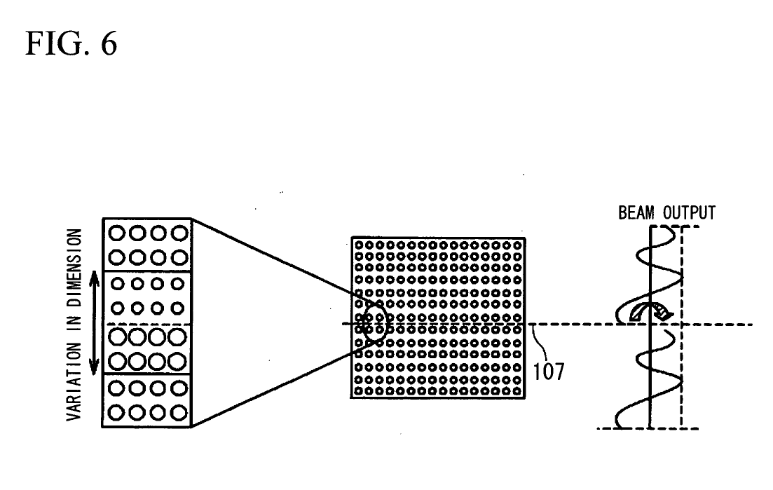

### DETAILED DESCRIPTION OF THE INVENTION

Now, referring to the accompanying drawings, an embodiment of the present invention is described below in detail. It should be noted that in this embodiment, it is exemplified that the electron-beam lithography method is executed by a program installed in a computer (i.e., a control device 2).

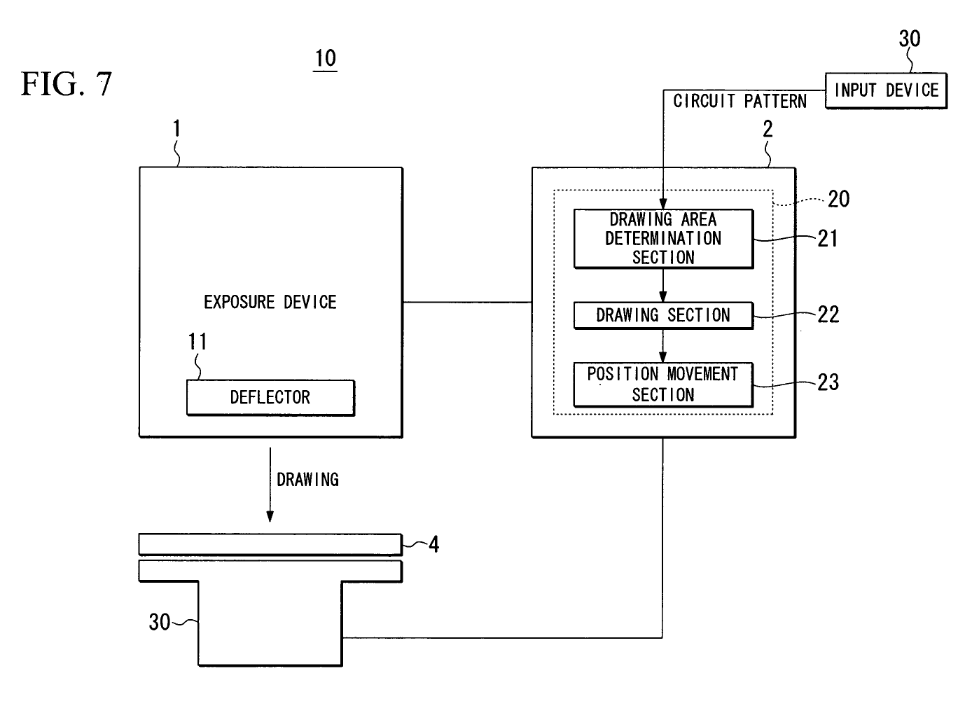

FIG. 7 shows the block diagram of the configuration of the electron-beam lithography apparatus 10 according to the embodiment of the present invention. The electron-beam lithography apparatus 10 is provided with: an exposure device 1 for making a drawing on a drawing target 4; and a control device 2 for controlling the operations of the exposure device 1 and a stage 30 with the drawing target 4 mounded thereon. In this embodiment, the drawing target 4 is assumed to be a photo mask used to draw the DRAM patterns on the semiconductor wafer. The present embodiment is easy to apply to the DRAM pattern, which has the areas with more repetitive patterns than its surrounding areas arranged in a reticular pattern. It should be noted that the patterns to be drawn according to the present embodiment are not limited to the DRAM patterns. Besides the DRAM patterns, the present embodiment may be applied to any pattern containing an area with more repetitive patterns than its surrounding areas, such as the pattern of a multi-functional large scale integrated circuit (LSI), in which the same chip mounts a plurality of functions.

The exposure device 1 has a deflector 11 disposed therein. The exposure device 1 draws patterns by irradiating the electron beam onto the drawing target 4. In this case, the deflector 11 scans the positions, at which the electron beam irradiates, to toggle the electron beam between on and off.

The control device 2 controls the operation of the exposure device 1. The control device 2 is configured by, for example, a computer containing a central processing unit (CPU), read-only memory (ROM), random-access memory (RAM), and the like, and realizes its function through the electron-beam lithography program 20 installed therein.

In addition, data of the circuit pattern to be drawn may be entered in the control device 2 via an input device 30.

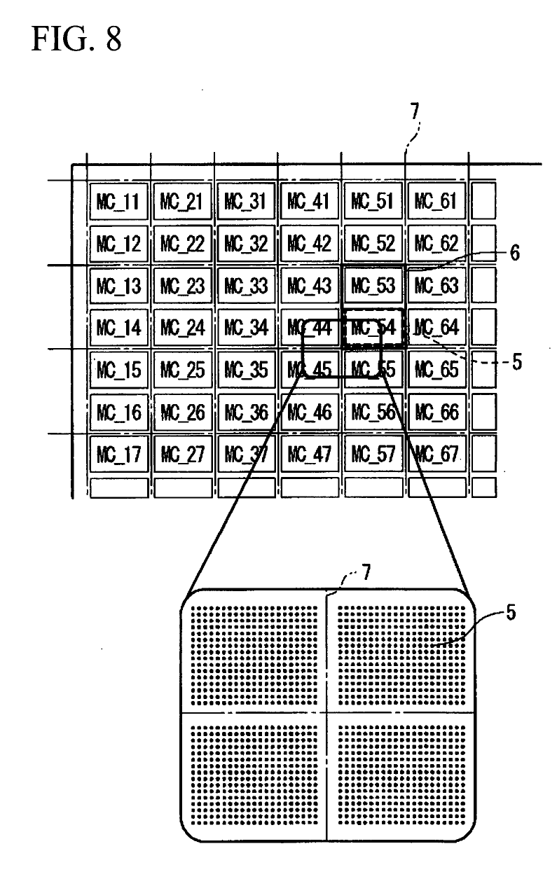

Now, the DRAM circuit pattern to be drawn in the embodiment of the present invention is described below. FIG. 8 is a schematic diagram showing the DRAM circuit pattern. In the DRAM circuit pattern, a plurality of memory cell mat areas 5 are arranged in a reticular pattern with a slight gap left between the adjacent ones. The memory cell mat area 5 is an area with the memory cells arranged in an array pattern therein, in which dot-patterns are regularly arranged. This means that the memory cell mat area 5 contains more repetitive patterns than its surrounding areas have. It should be noted that the length of one side of the memory cell mat area 5, drawn on the drawing target 4, is approximately 100 to 300 micrometers.

Next, the electron-beam lithography program 20 is described below. The electron drawing program 20 is provided with: a module for allowing the computer as the control device 2 to act as a drawing area determination section 21; a module for allowing the computer to act as a drawing section 22; and a module for allowing the computer to act as a position movement section 23.

The drawing area determination section 21 realizes the function of setting the area to be drawn. In this case, the drawing areas are set so as to split the whole circuit pattern into a plurality of areas. How to split the whole circuit pattern into the drawing areas is described later.

The drawing section 22 draws the circuit pattern on the drawing target 4 in each of the drawing areas by means of the exposure device 1. The position movement section 23 moves the stage 30 mounting the drawing target 4. As soon as drawing is finished in one drawing area, the stage 30 is moved by one drawing area by means of the position movement section 23, and drawing is initiated in the adjacent drawing area by means of the drawing section 22. These operations are repeated until the whole circuit pattern is drawn on the drawing target 4.

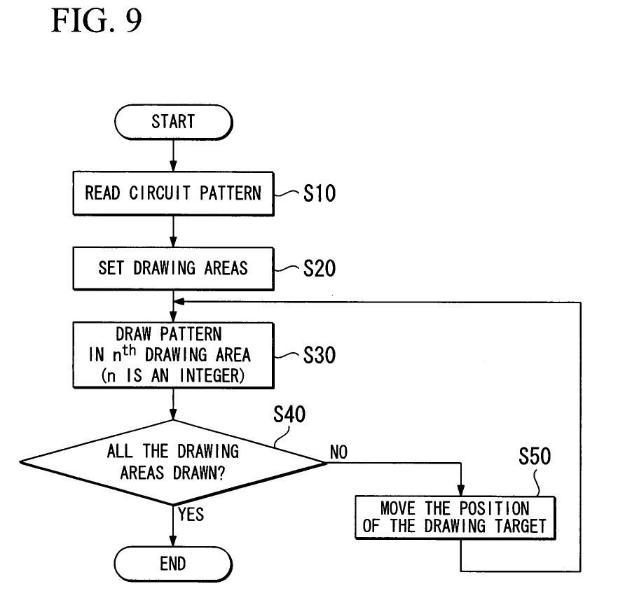

Next, the electron-beam lithography method according to the embodiment of the present invention is described below. FIG. 9 is a flowchart of the electron-beam lithography method according to the embodiment of the present invention. The electron-beam lithography method involves a process composed of steps S10 to S50. Each of the steps is in detail described below.

### Step S10: Reads the Circuit Pattern

First, data of the circuit pattern to be drawn is entered into the control device 2 via the input device 30.

### Step S20: Sets the Areas to be Drawn

Second, the drawing area determination section 21 sets the drawing areas based on the entered data on the circuit pattern. Referring to FIG. 8, the drawing areas 6 are described. The drawing area determination section 21 sets the boundary between the adjacent drawing areas 6 (i.e., the connection 7) so that the boundary is laid between the adjacent memory cell mat areas 5. In this embodiment of the present invention, each of the drawing areas 6 is set so that it corresponds to two vertically adjacent memory cell mat areas 5. It should be noted that each drawing area 6 may correspond to any number of memory cell mat areas 5 provided that the connection 7 is laid between the adjacent memory cell mat areas 5 and the drawing areas 6 are narrower than the allowable deflection area of the exposure device 1.

### Step S30 to S50: Draws the Circuit Pattern in Each Drawing Area

Third, the drawing section 22 draws the circuit pattern on the drawing target 4 by means of the exposure device 1. In this case, the circuit pattern is drawn in units of the drawing areas 6. This means that as soon as drawing is finished in one of the drawing areas 6 (step S30), it is determined whether drawing has been made in all the drawing areas (step S40). If any drawing area 6 with no pattern drawn is detected, the stage 30 mounting the drawing target 4 moves by one drawing area (step S50). Then, a drawing is made in the adjacent drawing area 6. On the other hand, at the step 40, when it is determined that a drawing has been made in all the drawing areas 6, the drawing process is brought to completion.

As described above, according to the embodiment of the present invention, no sudden deformation in pattern dimension due to a rapid change in beam output occurs in the memory cell mat areas 5 during the drawing process because the connection 7 is laid between the memory cell mat areas 5. Conventionally, when a rapid change in pattern dimension occurs in the memory cell mat areas 5, a sudden deformation in pattern dimension may occur in the area with more repetitive patterns than its surrounding areas. This may induce light interference in the site with the dimension deformed, causing a stripe-pattern or reticular-pattern of color shading to be observed in some cases. This type of stripe-pattern or reticular-pattern color shading is recognized as a lot of false defects during the optical defect inspection process. In contrast, according to the embodiment of the present invention, no sudden deformation in pattern dimension occurs in the area with more repetitive patterns than its surrounding areas, and thus the occurrence of stripe-pattern or reticular-pattern color shading being suppressed. In this case, a sudden deformation in pattern dimension may occur at the connection 7 laid between the memory cell mat areas 5. However, since the boundary between the memory cell mat areas 5 is not the area with more repetitive patterns than its surrounding areas, no light interference is induced. This means that no false defects are observed during the optical defect inspection process. Accordingly, false defect detection is suppressed during the optical defect inspection process, improving its yield.

When the circuit pattern is drawn by the conventional multi-pass drawing technique, throughput reduces because the same areas are scanned many times. In contrast, according to the embodiment of the present invention, the false defect detection can be suppressed during the optical defect inspection process with no loss in throughput because the single-pass drawing technique is applied.

It should be noted that the embodiment of the present invention has been described assuming that the drawing target 4 is the photo mask. However, it is self-evident truth for those skilled in the art that the present embodiment can be applied to the case in which the circuit pattern is drawn directly on the semiconductor wafer as the drawing target 4 in the absence of an intermediate photo mask.

It may be possible that the aforementioned electron-beam lithography program 20 is recorded on a computer-readable recording medium and then the electron-beam lithography program 20 recorded in the recording medium is read in a computer system, for example, the aforementioned computer, for execution to perform the foregoing steps. It should be noted that the computer system referred herein contains any operating system (OS) and peripheral hardware. The computer system having an Internet connection contains a home-page providing environment (home-page viewing environment). The computer-readable recording medium should include portable media such as a flexible disk, magnetic optical disk, ROM, CD (compact disk) -ROM, or storage devices including hard disk contained in the computer system, and those storing a program for a certain time period such as volatile memory (RAM) contained in the computer system, which acts as a server or client when the program is transferred through a network, for example the Internet or a communication line, for example a telephone line. The aforementioned electron beam lithography program 20 may be transmitted from the computer system containing it in a storage device to another computer system through a transmission medium or on a carrier running within the transmission medium. Herein, the transmission medium is a medium which has a function of transmitting information as in the network (communication network), for example the Internet or communication circuits (communication lines), for example a telephone line. The electron-beam lithography program 20 may be intended to partially implement the aforementioned function. It also may be a product provided by combining the aforementioned function with the program already recorded in the computer system, what is known as a difference file (difference program).

While preferred embodiments of the present invention have been described and illustrated above, it should be understood that these are exemplary of the present invention and are not to be considered as limiting. Additions, omissions, substitutions, and other modifications can be made without departing from the scope of the present invention. Accordingly, the present invention is not to be considered as being limited by the foregoing description, and is only limited by the scope of the appended claims.

What is claimed is:

1. An electron-beam lithography method comprising:
a drawing area setting step of splitting a circuit pattern containing a plurality of areas with high repetition rates, each of which having more repetitive patterns than surrounding areas of each of the areas with high repetition rates, into a plurality of drawing areas so that a boundary between adjacent drawing areas is laid between adjacent areas with high repetition rates; and
a drawing step of drawing the circuit pattern on a drawing target for each of the drawing areas.

2. The electron-beam lithography method as recited in claim 1, wherein the circuit pattern is a DRAM circuit pattern, and each of the areas with high repetition rates is a memory cell mat area containing an area where a plurality of memory cells are arranged into an array.

3. The electron-beam lithography method as recited in claim 1, wherein the drawing target is a mask used in an electron-beam lithography apparatus.

4. The electron-beam lithography method as recited in claim 1, wherein the drawing target is a semiconductor wafer.

5. The electron-beam lithography method as recited in claim 1, wherein a single-pass drawing is made on the drawing target at the drawing step.

6. The electron-beam lithography method as recited in claim 1, wherein each of the drawing areas is narrower than an area where an exposure device, which makes a drawing on the drawing target, can deflect an electron beam.

7. An electron-beam lithography apparatus comprising:
an exposure device which makes a drawing on a drawing target by means of an electron beam; and
a control device which controls the operation of the exposure device,
wherein the control device comprises:
a drawing area determination section which splits a circuit pattern containing a plurality of areas with high repetition rates, each of which having more repetitive patterns than surrounding areas of each of the areas with high repetition rates, into a plurality of drawing areas so that a boundary between adjacent drawing areas is laid between adjacent areas with high repetition rates; and
a drawing section which allows the exposure device to draw the circuit pattern on the drawing target for each of the drawing areas.

8. The electron-beam lithography apparatus as recited in claim 7, wherein the circuit pattern is a DRAM circuit pattern, and each of the areas with high repetition rates is a memory cell mat area containing an area where a plurality of memory cells are arranged into an array.

9. The electron-beam lithography apparatus as recited in claim 7, wherein the drawing target is a mask used in the electron-beam lithography apparatus.

10. The electron-beam lithography apparatus as recited in claim 7, wherein the drawing target is a semiconductor wafer.

11. The electron-beam lithography apparatus as recited in claim 7, wherein the drawing section allows the exposure device to make a single-pass drawing.

12. The electron-beam lithography apparatus as recited in claim 7, wherein each of the drawing areas is narrower than an area where the exposure device can deflect the electron beam.

13. An electron-beam lithography program which allows a computer to execute:
a drawing area setting step of splitting a circuit pattern containing a plurality of areas with high repetition rates, each of which having more repetitive patterns than surrounding areas of each of the areas with high repetition rates, into a plurality of drawing areas so that a boundary between adjacent drawing areas is laid between adjacent areas with high repetition rates; and
a drawing step of drawing the circuit pattern on a drawing target for each of the drawing areas.

14. The electron-beam lithography program as recited in claim 13, wherein the circuit pattern is a DRAM circuit pattern, and each of the areas with high repetition rates is a memory cell mat area containing an area where a plurality of memory cells are arranged into an array.

15. The electron-beam lithography program as recited in claim 13, wherein the drawing target is a mask used in an electron-beam lithography apparatus.

16. The electron-beam lithography program as recited in claim 13, wherein the drawing target is a semiconductor wafer.

17. The electron-beam lithography program as recited in claim 13, wherein a single-pass drawing is made on the drawing target at the drawing step.

18. The electron-beam lithography program as recited in claim 13, wherein each of the drawing areas is narrower than an area where an exposure device, which makes a drawing on the drawing target, can deflect an electron beam.
